(19) United States
(12) Patent Application Publication
(10) Pub. No.: US 2024/0395709 A1
(43) Pub. Date: Nov. 28, 2024

(54) SEMICONDUCTOR MEMORY DEVICE

(71) Applicant: Socionext Inc., Kanagawa (JP)

(72) Inventor: Yasumitsu SAKAI, Yokohama-shi (JP)

(21) Appl. No.: 18/796,017

(22) Filed: Aug. 6, 2024

Related U.S. Application Data
(63) Continuation of application No. PCT/JP2023/004041, filed on Feb. 7, 2023.

(30) Foreign Application Priority Data
Feb. 16, 2022 (JP) 2022-022205

(51) Int. Cl. H01L 23/528; G11C 5/06; G11C 17/12; H10B 20/00

(52) U.S. Cl. CPC H01L 23/5283; G11C 5/063; G11C 17/12; H01L 23/528; H01L 23/5286; H10B 20/38

(57) ABSTRACT

A semiconductor memory device includes: a word line extending in the X direction; a bit line extending in the Y direction, formed in a buried interconnect layer; and a ground power line extending in the Y direction. A memory cell includes a transistor provided between the bit line and the ground power line, and connected to the word line at its gate and to the bit line at its drain. The memory cell stores data depending on the presence or absence of connection between the source of the transistor and the ground power line.

### CROSS-REFERENCE TO RELATED APPLICATIONS

This is a continuation of International Application No. PCT/JP2023/004041 filed on Feb. 7, 2023, which claims priority to Japanese Patent Application No. 2022-022205 filed on Feb. 16, 2022. The entire disclosures of these applications are incorporated by reference herein.

### BACKGROUND

The present disclosure relates to a semiconductor memory device, and more particularly to a layout structure of a mask read only memory (ROM).

A mask ROM includes memory cells arranged in an array, and each memory cell is programmed to have a fixed data state during manufacture. A transistor constituting the memory cell is provided between a bit line and VSS and connected to a word line at its gate. Bit data “1” or “0” is stored in the memory cell depending on the presence or absence of connection between its source or drain and the bit line or VSS. The presence or absence of connection is realized by the presence or absence of a contact or a via, for example.

Also, as for a transistor, which is a basic constituent of an LSI, improvement in integration degree, reduction in operating voltage, and improvement in operating speed have been achieved by reducing (scaling) the gate length. In recent years, however, increase in off current due to excessive scaling and the resulting significant increase in power consumption have raised a problem. To solve this problem, three-dimensional transistors, such as a fin field effect transistor (FET) and a nanosheet FET, having a three-dimensional structure changed from the conventional planar structure have been vigorously studied.

International Patent Publication No. WO 2020/230665 discloses a layout structure of a ROM cell using a complementary FET (CFET).

In the mask ROM described in the cited patent document, interconnects in an M1 interconnect layer located above transistors are used as bit lines. As semiconductor integrated circuits are being further miniaturized, however, the resistance values of interconnects are becoming larger, and this causes problems such as decrease in the operating speed of the mask ROM due to the resistance of the bit lines. If the line width of the bit lines is made large to reduce the resistance of the bit lines, a problem of increase of the area will arise.

An objective of the present disclosure is presenting a layout structure of a mask ROM in which decrease in operating speed is curbed without increase in area.

### SUMMARY

According to the first mode of the present disclosure, a semiconductor memory device having a read only memory (ROM) cell, includes: a word line extending in a first direction; a bit line extending in a second direction perpendicular to the first direction, formed in a buried interconnect layer; and a ground power line extending in the second direction, wherein the ROM cell includes a transistor provided between the bit line and the ground power line, connected to the word line at its gate and to the bit line at its drain, and the ROM cell stores data depending on the presence or absence of connection between a source of the transistor and the ground power line.

According to the above mode, the ROM cell includes a transistor that is provided between the bit line and the ground power line and connected to the word line at its gate and to the bit line at its drain. The ROM cell stores data depending on the presence or absence of connection between the source of the transistor and the ground power line. Since the bit line is formed in the buried interconnect layer, the resistance value of the bit line can be reduced by increasing the thickness of the bit line in the depth direction. In this way, decrease in the operating speed of the mask ROM can be curbed without increase in area.

According to the second mode of the present disclosure, a semiconductor memory device having a read only memory (ROM) cell, includes: a word line extending in a first direction; a bit line extending in a second direction perpendicular to the first direction, formed in a buried interconnect layer; and a ground power line extending in the second direction, wherein the ROM cell includes a transistor provided between the bit line and the ground power line, connected to the word line at its gate, and the ROM cell stores data depending on whether a source and a drain of the transistor are connected to a same line, or different lines, out of the bit line and the ground power line.

According to the above mode, the ROM cell includes a transistor that is provided between the bit line and the ground power line and connected to the word line at its gate. The ROM cell stores data depending on whether the source and drain of the transistor are connected to a same line, or different lines, out of the bit line and the ground power line. Since the bit line is formed in the buried interconnect layer, the resistance value of the bit line can be reduced by increasing the thickness of the bit line in the depth direction. In this way, decrease in the operating speed of the mask ROM can be curbed without increase in area.

According to the third mode of the present disclosure, a semiconductor memory device having a read only memory (ROM) cell, includes: a word line extending in a first direction; a first bit line extending in a second direction perpendicular to the first direction, formed in a buried interconnect layer; a second bit line extending in the second direction, formed in a first interconnect layer located above the buried interconnect layer and electrically connected to the first bit line; and a ground power line extending in the second direction, formed in the first interconnect layer, wherein the ROM cell includes a transistor provided between the second bit line and the ground power line, connected to the word line at its gate, and the ROM cell stores data depending on whether a source and a drain of the transistor are connected to a same line, or different lines, out of the second bit line and the ground power line.

According to the above mode, the ROM cell includes a transistor that is provided between the second bit line and the ground power line and connected to the word line at its gate. The ROM cell stores data depending on whether the source and drain of the transistor are connected to a same line, or different lines, out of the second bit line and the ground power line. Since the first bit line that is electrically connected to the second bit line is formed in the buried interconnect layer, the resistance value of the first bit line can be reduced by increasing the thickness of the first bit line in the depth direction. In this way, decrease in the operating speed of the mask ROM can be curbed without increase in area.

According to the present disclosure, a layout structure of a mask ROM in which decrease in operating speed is curbed without increase in area can be presented.

### BRIEF DESCRIPTION OF THE DRAWINGS

FIG. 1 is a circuit diagram showing a configuration of a contact-type mask ROM as an example of the semiconductor memory device.

FIG. 2 is a plan view showing an example of the layout structure of a semiconductor memory device of the first embodiment.

FIGS. 3A-3C are cross-sectional views of the layout structure of FIG. 2.

FIG. 4 is a plan view showing another example of the layout structure of the semiconductor memory device of the first embodiment.

FIGS. 5A-5C are cross-sectional views of the layout structure of FIG. 4.

FIG. 6 is a plan view showing an example of the layout structure of a semiconductor memory device of Alteration 1 of the first embodiment.

FIG. 7 is a cross-sectional view of the layout structure of FIG. 6.

FIG. 8 shows a layout example of a memory array unit of the semiconductor memory device of Alteration 1 of the first embodiment.

FIG. 9 is a plan view showing an example of the layout structure of a semiconductor memory device of Alteration 2 of the first embodiment.

FIG. 10 is a cross-sectional view of the layout structure of FIG. 9.

FIG. 11 shows a layout example of a memory array unit of the semiconductor memory device of Alteration 2 of the first embodiment.

FIG. 12 is a circuit diagram showing a configuration of a contact-type mask ROM as an example of the semiconductor memory device.

FIG. 13 is a plan view showing an example of the layout structure of a semiconductor memory device of the second embodiment.

FIG. 14 is a plan view showing an example of the layout structure of a semiconductor memory device of Alteration 1 of the second embodiment.

FIG. 15 is a plan view showing an example of the layout structure of a semiconductor memory device of Alteration 2 of the second embodiment.

FIG. 16 is a cross-sectional view of the layout structure of FIG. 15.

### DETAILED DESCRIPTION

Embodiments of the present disclosure will be described with reference to the accompanying drawings. As used herein, “VDD” and “VSS” refer to the power supply voltages or the power supplies themselves. Also, the source region and drain region of a transistor are herein called the “nodes” of the transistor as appropriate. That is, one node of a transistor refers to the source or drain of the transistor, and both nodes of a transistor refer to the source and drain of the transistor.

### First Embodiment

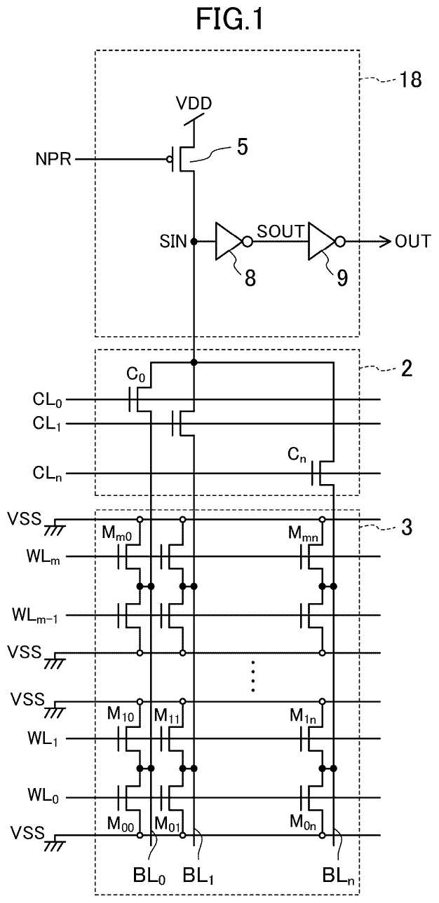

FIG. 1 is a circuit diagram showing a configuration of a contact-type mask ROM as an example of the semiconductor memory device. The mask ROM shown in FIG. 1 is a ROM in which whether or not the source of a memory cell transistor is connected to a ground line VSS through a contact is made to correspond to “0” or “1” of memory data.

In FIG. 1, the mask ROM includes a memory cell array 3, a column decoder 2, and a sense amplifier 18.

The memory cell array 3 is constituted by memory cells Mij (i=0 to m, j=0 to n) of n-type MOS transistors arranged in a matrix. The gates of the memory cells Mij are connected 10 to corresponding word lines WLi that are common for each row, and the drains thereof are connected to corresponding bit lines BLj that are common for each column. The sources of the memory cells Mij are connected to the ground potential VSS when the memory data is intended to be “0”, and are not connected to the ground potential VSS when it is intended to be “1”.

The column decoder 2 is constituted by n-type MOS transistors Cj. The drains of the n-type MOS transistors Cj are all connected together as a common drain, the gates thereof are connected to corresponding column selection signal lines CLj, and the sources thereof are connected to the corresponding bit lines BLj.

The sense amplifier 18 includes a precharge p-type MOS transistor 5, an inverter 8 that judges the output data of the memory cells Mij, and an inverter 9 that buffers the output signal of the inverter 8. A precharge signal NPR is input into the gate of the p-type MOS transistor 5, the power supply voltage VDD is supplied to the source thereof, and the drain thereof is connected to the common drain of the n-type MOS transistors Cj. The inverter 8, receiving a signal SIN from the common drain of the n-type MOS transistors Cj, judges the output data of the memory cells Mij. The inverter 9, receiving an output signal SOUT of the inverter 8, outputs memory data of the memory cells Mij.

The operation of the mask ROM of FIG. 1 will be described taking as an example the case of reading data of the memory cell M00.

First, among the column selection signal lines CLj, CL0 is made high and the other CL1 to CLn are made low. This turns on the transistor C0, among the transistors constituting the column decoder 2, and turns off the other transistors C1 to Cn. Also, a word line WL0 is changed from a low level as the non-selected state to a high level as the selected state.

The precharge signal NPR is then changed from high to low, to turn on the precharge p-type MOS transistor 5.

In the case where the source of the memory cell M00 is connected to the ground potential VSS, since the current capability of the memory cell M00 is greater than that of the precharge p-type MOS transistor 5, the input signal SIN of the inverter 8 becomes lower in voltage than the switching level of the inverter 8. Therefore, the output signal SOUT of the inverter 8 keeps high, and an output signal OUT of the inverter 9 keeps low.

On the other hand, in the case where the source of the memory cell M00 is not connected to the ground potential VSS, the bit line BL0 is charged by the precharge p-type MOS transistor 5, and thus the input signal SIN of the inverter 8 becomes higher in voltage than the switching level of the inverter 8. Therefore, the output signal SOUT of the inverter 8 becomes low, and the output signal OUT of the inverter 9 becomes high.

That is, when the source of a memory cell is connected to VSS, a low level is output (memory data “0”), and when the source of a memory cell is not connected to VSS, a high level is output (memory data “1”).

Note that, in the mask ROM according to this disclosure, as the method of storing a value in each memory cell, there are a case of setting the value by connection or disconnection between the memory cell and VSS and a case of setting the value by connection or disconnection between the memory cell and a bit line.

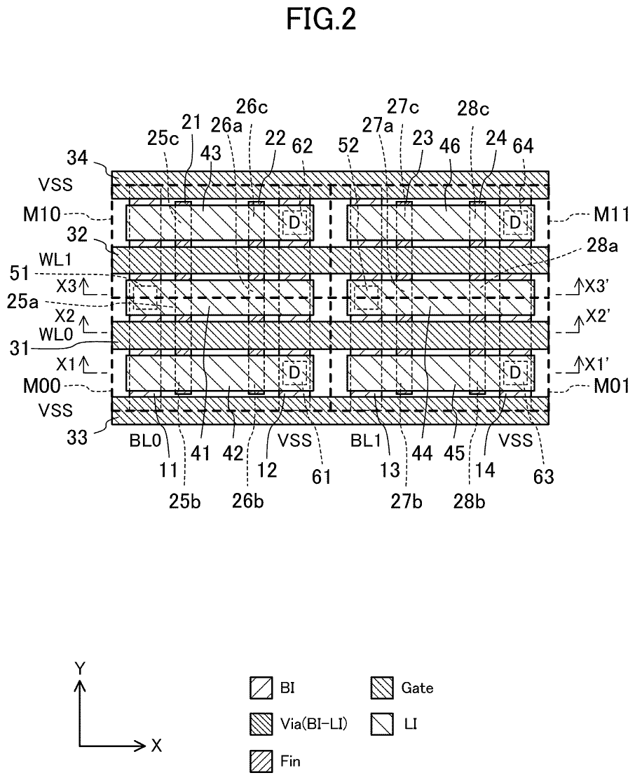

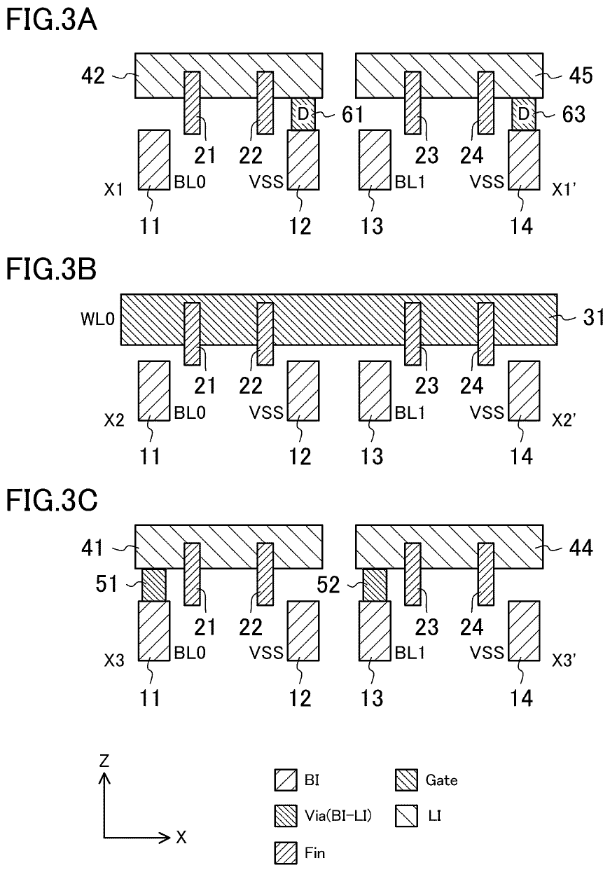

FIGS. 2 and 3A-3C are views showing an example of the layout structure of a mask ROM of the first embodiment. Specifically, FIG. 2 is a plan view of a memory cell array, and FIGS. 3A-3C are cross-sectional views of the memory cell array of FIG. 2 taken horizontally as viewed in plan, where FIG. 3A shows a cross section taken along line X1-X1′, FIG. 3B shows a cross section taken along line X2-X2′, and FIG. 3C shows a cross section taken along line X3-X3′.

In the following description, in the plan views such as FIG. 2, the horizontal direction in the figure is called an X direction (corresponding to the first direction), the vertical direction in the figure is called a Y direction (corresponding to the second direction), and the direction perpendicular to the substrate plane is called a Z direction (corresponding to the depth direction). Note also that the X direction is the direction in which gate interconnects and word lines extend, and the Y direction, which is the channel direction, is the direction in which bit lines extend.

Also, in the drawings for the first embodiment, each contact determining the memory value of a memory cell is marked with the letter “D”.

FIG. 2 corresponds to the layout of (2×2) bits, and the broken lines define the bounds of the individual bits. That is, FIG. 2 shows a configuration of an array of memory cells, two arranged in the X direction and two in the Y direction. The memory cells are inverted in the Y direction every other row in the Y direction. In FIG. 2, the two memory cells, lower and upper, on the left in the figure correspond to the memory cells M00 and M10, respectively, in the circuit diagram of FIG. 1, and the two memory cells, lower and upper, on the right in the figure correspond to the memory cells M01 and M11, respectively, in the circuit diagram of FIG. 1.

As shown in FIG. 2, interconnects 11, 12, 13, and 14 extending in the Y direction are formed in a buried interconnect layer. In FIG. 2 and other drawings, the buried interconnects are abbreviated as BI. The buried interconnects 11 and 13 respectively correspond to the bit lines BL0 and BL1, and the buried interconnects 12 and 14 correspond to the ground lines supplying VSS.

Fin structures 21, 22, 23, and 24 extend in the Y direction. The memory cells M00 and M10 each have two fin FETs formed of the fin structures 21 and 22, and the memory cells M01 and M11 each have two fin FETs formed of the fin structures 23 and 24. Note that each memory cell may have one fin FET or three or more fin FETs.

Gate interconnects 31 and 32 extending in parallel in the X direction are formed. The gate interconnects 31 and 32 surround the peripheries of the fin structures 21, 22, 23, and 24 through gate insulating films (not shown). That is, the gate interconnect 31 corresponds to the word line WL0 and is connected to the gates of the fin FETs of the memory cells M00 and M01. The gate interconnect 32 corresponds to the word line WL1 and is connected to the gates of the fin FETs of the memory cells M10 and M11.

Dummy gate interconnects 33 and 34 extending in the X direction are formed and supply VSS.

Local interconnects 41, 42, 43, 44, 45, and 46 extending in the X direction are formed. In FIG. 2 and other drawings, the local interconnects are abbreviated as LI. The local interconnects 41, 42, 43, 44, 45, and 46 are connected to the sources or drains of the fin FETs of the corresponding memory cells. Specifically, the local interconnect 41 is connected to portions 25a and 26a of the fin structures 21 and 22 that are to be the common drains of the fin FETs of the memory cells M00 and M10. The local interconnect 42 is connected to portions 25b and 26b of the fin structures 21 and 22 that are to be the sources of the fin FETs of the memory cell M00. The local interconnect 43 is connected to portions 25c and 26c of the fin structures 21 and 22 that are to be the sources of the fin FETs of the memory cell M10. The local interconnect 44 is connected to portions 27a and 28a of the fin structures 23 and 24 that are to be the common drains of the fin FETs of the memory cells M01 and M11. The local interconnect 45 is connected to portions 27b and 28b of the fin structures 23 and 24 that are to be the sources of the fin FETs of the memory cell M01. The local interconnect 46 is connected to portions 27c and 28c of the fin structures 23 and 24 that are to be the sources of the fin FETs of the memory cell M11.

The local interconnect 41 is connected to the buried interconnect 11 through a contact 51. The local interconnect 44 is connected to the buried interconnect 13 through a contact 52.

Contacts 61, 62, 63, and 64 determine the memory values of the memory cells by their presence or absence. The contact 61, when formed, connects the local interconnect 42 and the buried interconnect 12 supplying VSS. The contact 62, when formed, connects the local interconnect 43 and the buried interconnect 12 supplying VSS. The contact 63, when formed, connects the local interconnect 45 and the buried interconnect 14 supplying VSS. The contact 64, when formed, connects the local interconnect 46 and the buried interconnect 14 supplying VSS.

The buried interconnect layer is formed to be buried in the substrate or a shallow trench isolation (STI). For a buried interconnect, therefore, the resistance value can be reduced by increasing the length (thickness) of the buried interconnect in the depth direction. Thus, by forming the bit lines BL0 and BL1 as the buried interconnects 11 and 13, it is possible to curb decrease in the performance of the mask ROM without increasing the area.

Also, by forming the ground lines supplying VSS as the buried interconnects 12 and 14, in addition to the bit lines BL0 and BL1, the ground lines can be made to function as shield interconnects between the bit lines. It is therefore possible to prevent malfunctions, etc. caused by crosstalk noise.

As described above, according to this embodiment, the ROM cell M00, for example, is provided between the bit line 11 and the ground power line 12, and includes a fin FET connected to the word line 31 at its gate and to the bit line 11 at its drain. The ROM cell M00 stores data depending on the presence or absence of connection between the source of the fin FET and the ground power line 12. Here, since the bit line 11 is formed in the buried interconnect layer, the resistance value of the bit line 11 can be reduced by increasing the thickness thereof in the depth direction. In this way, decrease in the operating speed of the mask ROM can be curbed without increase in area.

While the transistor included in the memory cell is a fin FET in the layout structure example described above, the transistor type is not limited to this but may be a nanosheet FET, for example. This also applies to an embodiment to follow.

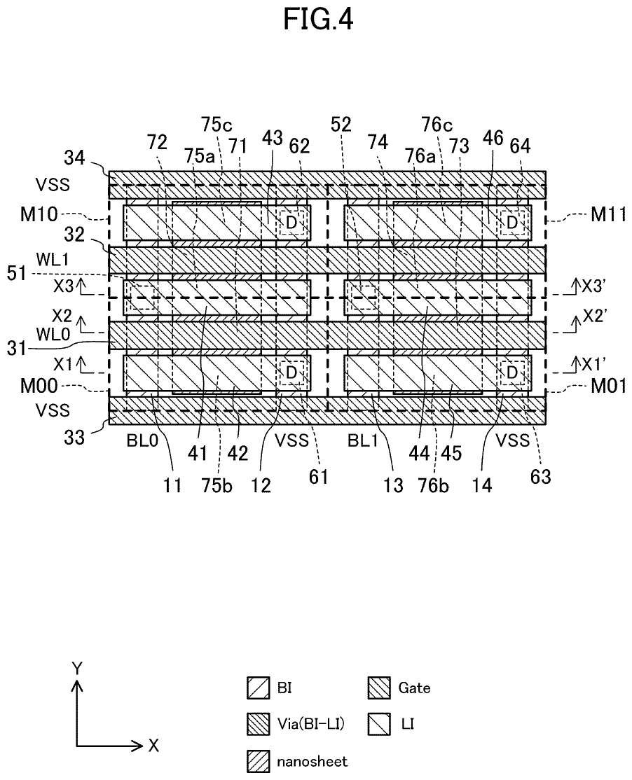

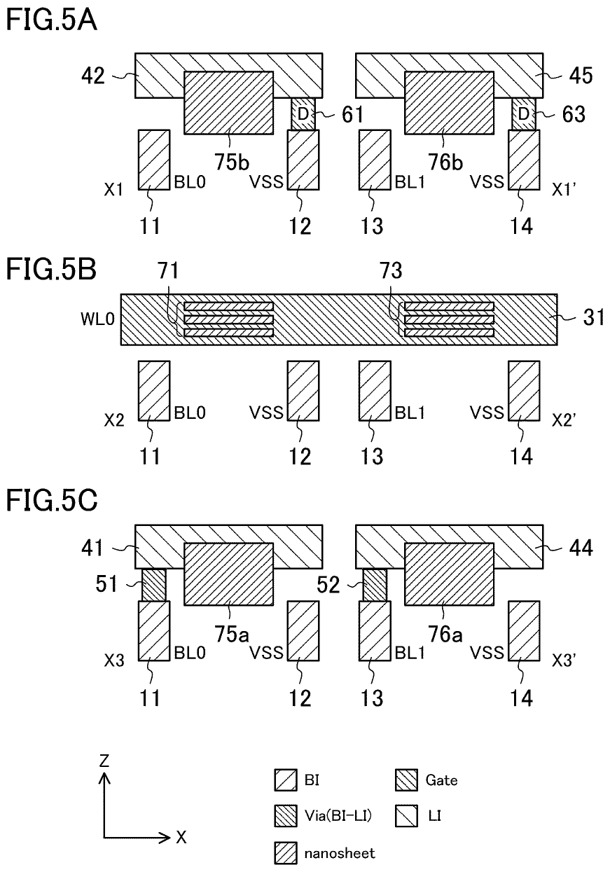

FIGS. 4 and 5A-5C are views showing another example of the layout structure of the mask ROM of the first embodiment. Specifically, FIG. 4 is a plan view of a memory cell array, and FIGS. 5A-5C are cross-sectional views of the memory cell array of FIG. 4 taken horizontally as viewed in plan, where FIG. 5A shows a cross section taken along line X1-X1′, FIG. 5B shows a cross section taken along line X2-X2′, and FIG. 5C shows a cross section taken along line X3-X3′. In FIGS. 4 and 5A-5C, components in common with FIGS. 2 and 3A-3C are denoted by the same reference characters, and detailed description of such components is omitted here in some cases.

In the layout structure in FIGS. 4 and 5A-5C, each memory cell has a nanosheet FET. That is, the memory cells M00, M10, M01, and M11 have nanosheets 71, 72, 73, and 74, respectively, each composed of three sheets. In FIG. 4, a pad 75a made of a semiconductor layer of integral structure connected to the three sheets is formed between the nanosheets 71 and 72. Pads 75b and 75c, each made of a semiconductor layer of integral structure connected to the three sheets, are formed on the lower side of the nanosheets 71 and on the upper side of the nanosheets 72, respectively, in the figure. A pad 76a made of a semiconductor layer of integral structure connected to the three sheets is formed between the nanosheets 73 and 74. Pads 76b and 76c, each made of a semiconductor layer of integral structure connected to the three sheets, are formed on the lower side of the nanosheets 73 and on the upper side of the nanosheets 74, respectively, in the figure.

The pad 75a is to be the drain of the memory cells M00 and M10 and connected to the local interconnect 41. The pad 75b is to be the source of the memory cell M00 and connected to the local interconnect 42. The pad 75c is to be the source of the memory cell M10 and connected to the local interconnect 43. The pad 76a is to be the drain of the memory cells M01 and M11 and connected to the local interconnect 44. The pad 76b is to be the source of the memory cell M01 and connected to the local interconnect 45. The pad 76c is to be the source of the memory cell M11 and connected to the local interconnect 46.

In the layout structure shown in FIGS. 4 and 5A-5C, also, a similar effect to that in the layout structure shown in FIGS. 2 and 3A-3C is obtained.

While each nanosheet FET has a stacked structure of three sheets in the layout structure example described above, it is not limited to this. Some or all of the nanosheet FETs may have one nanosheet, or a stacked structure of two, four, or more sheets.

Also, while the cross-sectional shape of the nanosheets is illustrated as rectangular in the above layout structure, it is not limited to this. For example, the shape may be square, circular, or oval.

### <Alteration 1>

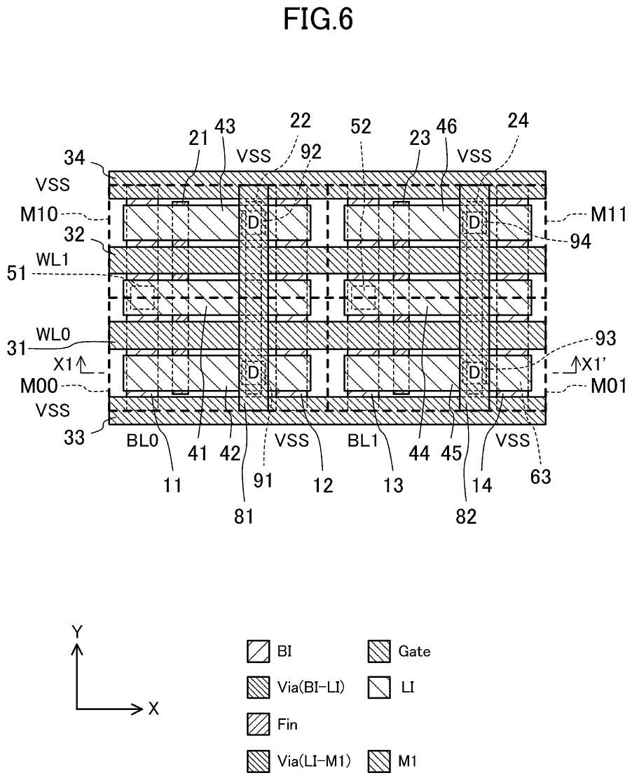

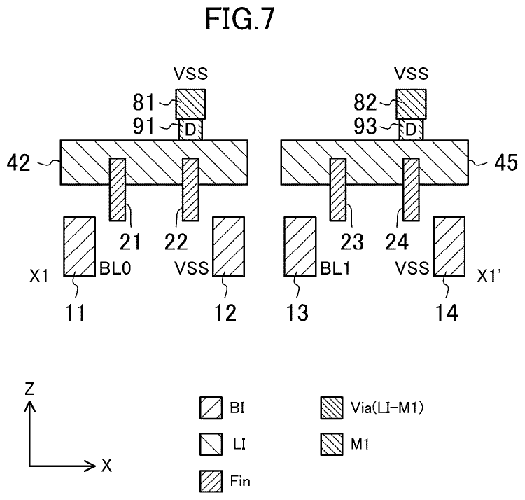

FIGS. 6 and 7 are views showing an example of the layout structure of a mask ROM of Alteration 1 of the first embodiment. Specifically, FIG. 6 is a plan view of a memory cell array, and FIG. 7 is a cross-sectional view of the memory cell array of FIG. 6 taken horizontally as viewed in plan along line X1-X1′. In FIGS. 6 and 7, components in common with FIGS. 2 and 3A-3C are denoted by the same reference characters, and detailed description of such components is omitted here in some cases.

In this alteration, interconnects 81 and 82 extending in the Y direction are provided in an M1 interconnect layer. The interconnects 81 and 82 correspond to the ground lines supplying VSS. Contacts 91, 92, 93, and 94 are provided between the local interconnects 42, 43, 45, and 46 that are to be the sources of the memory cells and the M1 interconnects 81 and 82 supplying VSS. The contacts 91, 92, 93, and 94 determine the memory values of the memory cells by their presence or absence. No contacts are provided between the local interconnects 42, 43, 45, and 46 and the buried interconnects 12 and 14 supplying VSS.

The contact 91, when formed, connects the local interconnect 42 and the M1 interconnect 81 supplying VSS. The contact 92, when formed, connects the local interconnect 43 and the M1 interconnect 81 supplying VSS. The contact 93, when formed, connects the local interconnect 45 and the M1 interconnect 82 supplying VSS. The contact 94, when formed, connects the local interconnect 46 and the M1 interconnect 82 supplying VSS.

In this alteration, since the memory values of the memory cells are set by contacts located at upper positions compared with the contacts in the first embodiment, it is possible to shorten the manufacturing time for changing the memory values of the memory cells. Note that, when no consideration is made to shorten the manufacturing time, contacts may be provided between local interconnects that are to be the sources of memory cells and buried interconnects supplying VSS.

Also, in this alteration, the interconnects 12 and 14 supplying VSS formed in the buried interconnect layer are not connected to anywhere inside the memory cell. However, as will be described later, the interconnects 12 and 14 supplying VSS and the M1 interconnects 81 and 82 supplying VSS are mutually connected outside the memory cell array. With the placement of the buried interconnects 12 and 14 supplying VSS, power supply is strengthened, and the stability of the operation of the memory cells improves. In addition, the buried interconnects 12 and 14 supplying VSS can be made to function as shield interconnects between the bit lines, and with this, malfunctions, etc. caused by crosstalk noise can be prevented. Note however that the buried interconnects 12 and 14 supplying VSS may be omitted in this alteration.

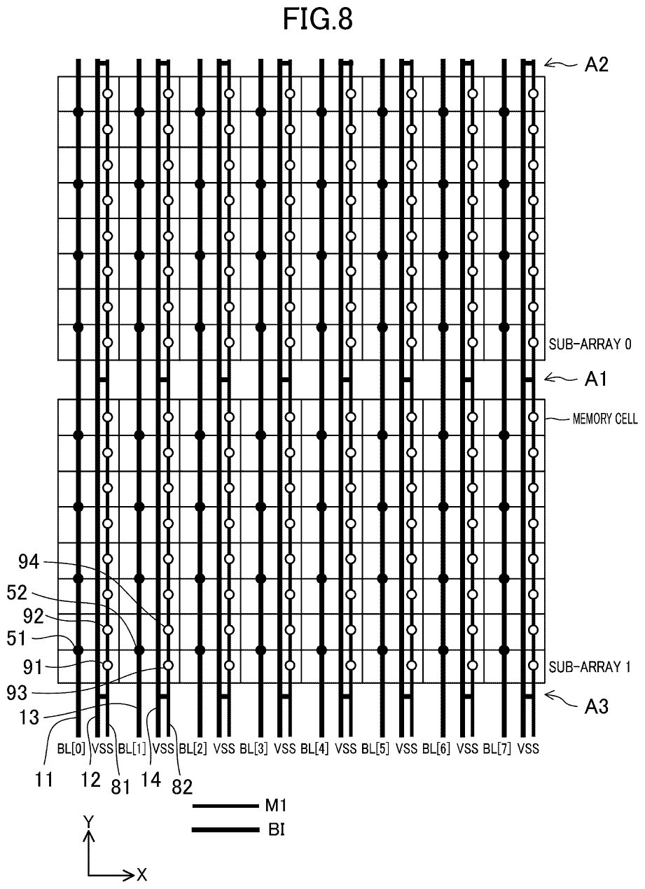

FIG. 8 shows a layout example of a memory array unit of the semiconductor memory device of this alteration. Note that, although memory cells are diagrammatically illustrated as rectangles in FIG. 8, each memory cell has a structure shown in FIGS. 6 and 7.

The memory array unit of FIG. 8 includes two sub-arrays 0 and 1, although the number of sub-arrays included in the memory array unit is not limited to this. The sub-arrays 0 and 1 each have (8×8) memory cells, although the number of memory cells included in each sub-array is not limited to this. Also, portions A1, A2, and A3 in which no memory cell is formed are respectively provided between the sub-arrays 0 and 1, on the upper side of the sub-array 0, and on the lower side of the sub-array 1 in the figure.

In the sub-arrays 0 and 1, bit lines BL formed in the buried interconnect layer and VSS line pairs formed in the buried interconnect layer and the M1 interconnect layer extend in the Y direction. In FIG. 8, four memory cells located in the lower-left corner of the sub-array 1 in the figure correspond to the memory cells M00, M01, M10, and M11 shown in FIG. 6, and the interconnects corresponding to the buried interconnects 11, 12, 13, and 14 and the M1 interconnects 81 and 82 are denoted by the same reference characters. The memory cells are placed adjacently in the Y direction, whereby the buried interconnects, and the M1 interconnects, are mutually connected, forming the bit lines BL in the buried interconnect layer and the VSS line pairs in the buried interconnect layer and the M1 interconnect layer.

In each memory cell, a bit line BL formed in the buried interconnect layer is connected to a local interconnect, which is connected to the drain of the corresponding transistor, through a contact. In FIG. 8, contacts connecting the bit lines BL and the local interconnects are indicated by black circles on the boundaries between memory cells. For the four memory cells in the lower-left corner of the sub-array 1 in the figure, the black circles corresponding to the contacts 51 and 52 shown in FIG. 6 are denoted by the same reference characters.

In each memory cell, a VSS line formed in the M1 interconnect layer is connected to, or not connected to, a local interconnect, which is connected to the source of the corresponding transistor, according to the memory value. In FIG. 8, the positions where contacts for connecting the VSS lines formed in the M1 interconnect layer and the local interconnects are located are indicated by white circles. For the four memory cells in the lower-left corner of the sub-array 1 in the figure, the white circles corresponding to the contacts 91, 92, 93, and 94 shown in FIG. 6 are denoted by the same reference characters. The VSS lines formed in the buried interconnect layer are not connected to the transistors.

In the portion A1 between the sub-arrays 0 and 1, the portion A2 on the upper side of the sub-array 0, and the portion A3 on the lower side of the sub-array 1 in the figure, each VSS line pair, i.e., the VSS line formed in the M1 interconnect layer and the VSS line formed in the buried interconnect layer are mutually connected, whereby power supply is strengthened.

### <Alteration 2>

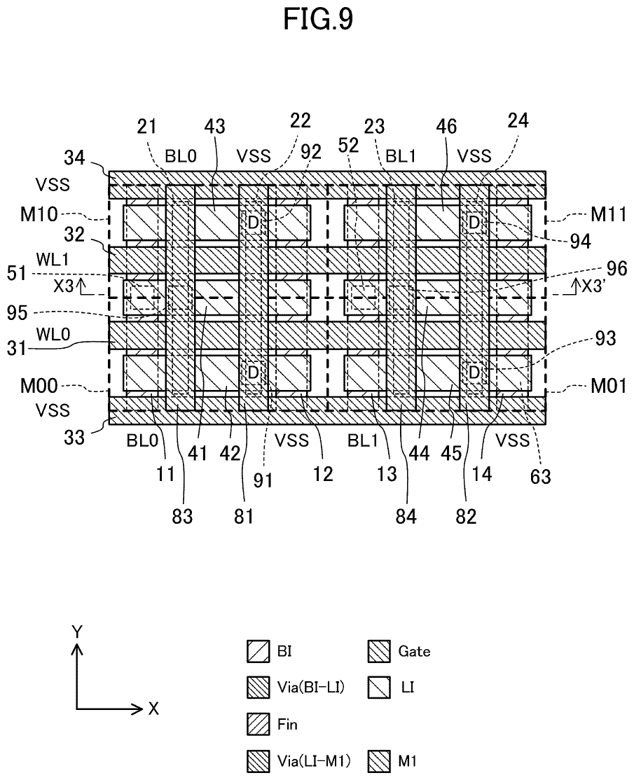

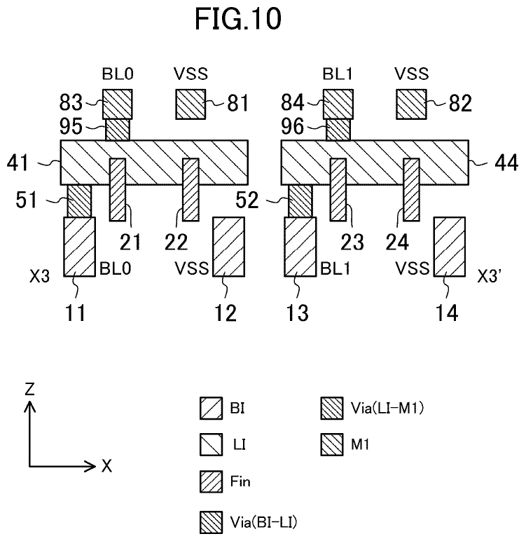

FIGS. 9 and 10 are views showing an example of the layout structure of a mask ROM of Alteration 2 of the first embodiment. Specifically, FIG. 9 is a plan view of a memory cell array, and FIG. 10 is a cross-sectional view of the memory cell array of FIG. 9 taken horizontally as viewed in plan along line X3-X3′. In FIGS. 9 and 10, components in common with FIGS. 2 and 3A-3C and FIGS. 6 and 7 are denoted by the same reference characters, and detailed description of such components is omitted here in some cases.

In this alteration, in addition to the interconnects 81 and 82 supplying VSS, interconnects 83 and 84 extending in the Y direction are provided in the M1 interconnect layer. The M1 interconnects 83 and 84 correspond to the bit lines BL0 and BL1, respectively. The M1 interconnect 83 is connected to the local interconnect 41 through a contact 95, and the M1 interconnect 84 is connected to the local interconnect 44 through a contact 96.

In this alteration, the bit line BL0 is constituted by the buried interconnect 11 and the M1 interconnect 83, and the bit line BL1 is constituted by the buried interconnect 13 and the M1 interconnect 84. With this, the resistance values of the bit lines BL0 and BL1 can be further reduced. Also, the M1 interconnects 81 and 82 supplying VSS can be made to function as shield interconnects between the bit lines formed in the M1 interconnect layer, and with this, malfunctions, etc. caused by crosstalk noise can be prevented.

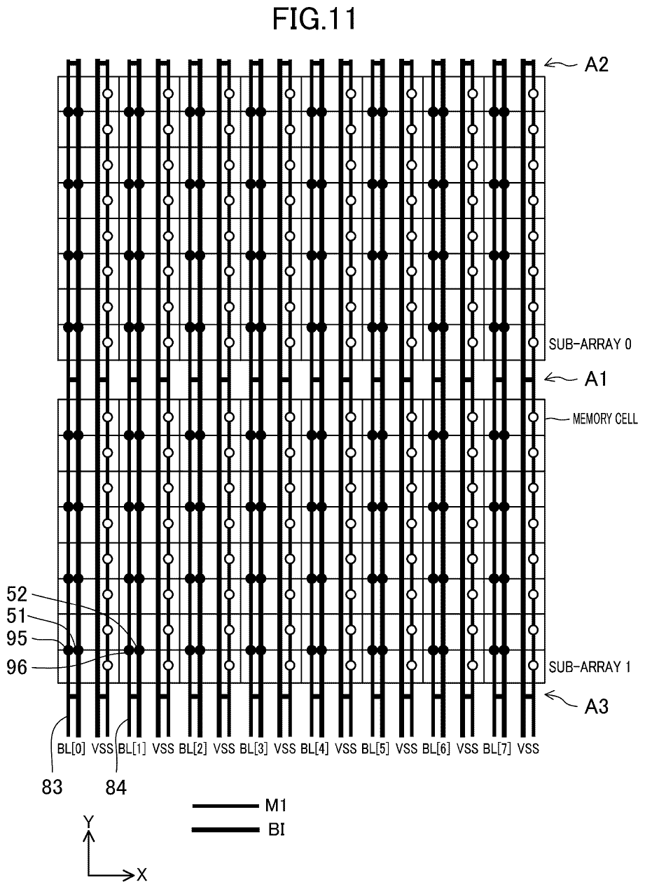

FIG. 11 shows a layout example of a memory array unit of the semiconductor memory device of this alteration. In FIG. 11, the basic configuration and the expression style are similar to those in FIG. 8, and description on configurations easily known by analogy from FIG. 8 and the related description is omitted here in some cases.

In the sub-arrays 0 and 1, bit line BL pairs formed in the buried interconnect layer and the M1 interconnect layer and the VSS line pairs formed in the buried interconnect layer and the M1 interconnect layer extend in the Y direction. In FIG. 11, four memory cells located in the lower-left corner of the sub-array 1 in the figure correspond to the memory cells M00, M01, M10, and M11 shown in FIG. 9, and the interconnects corresponding to the M1 interconnects 83 and 84 are denoted by the same reference characters.

In each memory cell, a bit line BL formed in the M1 interconnect layer is connected to a local interconnect, which is connected to the drain of the corresponding transistor, through a contact. In FIG. 11, contacts connecting the bit lines BL formed in the M1 interconnect layer and the local interconnects are indicated by black circles on the boundaries between memory cells. For the four memory cells in the lower-left corner of the sub-array 1 in the figure, the black circles corresponding to the contacts 95 and 96 shown in FIG. 9 are denoted by the same reference characters.

In the portion A1 between the sub-arrays 0 and 1, the portion A2 on the upper side of the sub-array 0, and the portion A3 on the lower side of the sub-array 1 in the figure, each bit line BL pair, i.e., the bit line formed in the M1 interconnect layer and the bit line formed in the buried interconnect layer are mutually connected. Also, as in Alteration 1 described above, each VSS line pair, i.e., the VSS line formed in the M1 interconnect layer and the VSS line formed in the buried interconnect layer are mutually connected.

Note that, in FIG. 11, for all memory cells, both the bit line formed in the M1 interconnect layer and the bit line formed in the buried interconnect layer are connected to the local interconnect connected to the drain of the corresponding transistor. It is however not necessarily required to connect both the bit line formed in the M1 interconnect layer and the bit line formed in the buried interconnect layer to the corresponding local interconnect, but only required to connect at least either one to the corresponding local interconnect in each memory cell.

For example, for all memory cells, only the bit line formed in the M1 interconnect layer may be connected to the corresponding local interconnect. Conversely, for all memory cells, only the bit line formed in the buried interconnect layer may be connected to the corresponding local interconnect. Otherwise, while the bit line formed in the M1 interconnect layer may be connected to the corresponding local interconnect for all memory cells, the bit line formed in the buried interconnect layer may be connected to the corresponding local interconnect for some memory cells. Conversely, while the bit line formed in the buried interconnect layer may be connected to the corresponding local interconnect for all memory cells, the bit line formed in the M1 interconnect layer may be connected to the corresponding local interconnect for some memory cells.

Alternatively, the bit line formed in the M1 interconnect layer may be connected to the corresponding local interconnect for some memory cells, and the bit line formed in the buried interconnect layer may be connected to the corresponding local interconnect for the remaining memory cells. In this case, for example, the memory cells in which the bit line formed in the M1 interconnect layer is connected to the corresponding local interconnect and the memory cells in which the bit line formed in the buried interconnect layer is connected to the corresponding local interconnect may be arranged alternately in the X direction and the Y direction.

By omitting some of connections between the local interconnects and the bit line pairs in the memory array unit as in the configurations described above, the load capacitances of the bit lines can be reduced.

### Second Embodiment

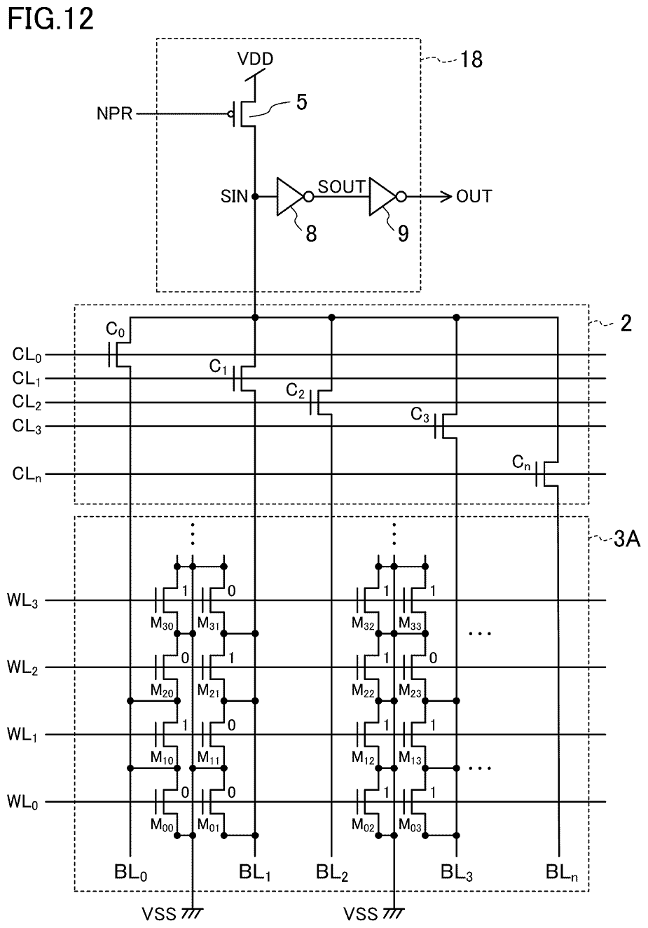

FIG. 12 is a circuit diagram showing a configuration of a mask ROM as an example of the semiconductor memory device. The mask ROM shown in FIG. 12 is a ROM in which whether the source and drain of a memory cell transistor are connected to a same line, or different lines, out of a bit line and a ground power line, is made to correspond to “1” or “0” of memory data.

In FIG. 12, the mask ROM includes a memory cell array 3A, a column decoder 2, and a sense amplifier 18.

The memory cell array 3A is constituted by memory cells Mij (i=0 to m, j=0 to n) of n-type MOS transistors arranged in a matrix. The gates of the memory cells Mij are connected to corresponding word lines WLi that are common for each row. The sources and drains of the memory cells Mij are connected to corresponding bit lines BLj or the ground power line VSS. When the memory data of a memory cell Mij is intended to be “0”, one of the source and the drain is connected to a bit line BLj and the other is connected to the ground power line VSS. On the other hand, when the memory data of a memory cell Mij is intended to be “1”, both the source and the drain are connected to a bit line BLj or the ground power line VSS.

The column decoder 2 is constituted by n-type MOS transistors Cj. The drains of the n-type MOS transistors Cj are all connected together as a common drain, the gates thereof are connected to corresponding column selection signal lines CLj, and the sources thereof are connected to the corresponding bit lines BLj.

The sense amplifier 18 includes a precharge p-type MOS transistor 5, an inverter 8 that judges the output data of the memory cells Mij, and an inverter 9 that buffers the output signal of the inverter 8. A precharge signal NPR is input into the gate of the p-type MOS transistor 5, the power supply voltage VDD is supplied to the source thereof, and the drain thereof is connected to the common drain of the n-type MOS transistors Cj. The inverter 8, receiving a signal SIN from the common drain of the n-type MOS transistors Cj, judges the output data of the memory cells Mij. The inverter 9, receiving an output signal SOUT of the inverter 8, outputs memory data of the memory cells Mij.

The operation of the mask ROM of FIG. 12 will be described taking as an example the case of reading data of memory cells M00 and M10.

First, among the column selection signal lines CLj, CL0 is made high and the other CL1 to CLn are made low. This turns on C0, among the transistors constituting the column decoder 2, and turns off the other C1 to Cn. Also, the word line WL0 is changed from a low level as the non-selected state to a high level as the selected state.

The precharge signal NPR is then changed from high to low, to turn on the precharge p-type MOS transistor 5.

In the memory cell M00, one of the source and the drain is connected to a bit line BL0 and the other is connected to the ground power line VSS. Therefore, since a current flows from the bit line BL0 to the ground power line VSS through the memory cell M00, the input signal SIN of the inverter 8 becomes lower in voltage than the switching level of the inverter 8. Thus, the output signal SOUT of the inverter 8 keeps high, and an output signal OUT of the inverter 9 keeps low.

In the case of reading data of the memory cell M10, the word line WL1 is changed from the low level as the non-selected state to the high level as the selected state.

In the memory cell M10, both the source and the drain are connected to the bit line BL0. Therefore, since no current flows to the bit line BL0, the input signal SIN of the inverter 8 becomes higher in voltage than the switching level of the inverter 8. Thus, the output signal SOUT of the inverter 8 becomes low, and the output signal OUT of the inverter 9 becomes high.

That is, when one of the source and drain of a memory cell is connected to a bit line and the other is connected to the ground power line, a low level is output (memory data “0”), and when both the source and drain of a memory cell are connected to a bit line or the ground power line, a high level is output (memory data “1”).

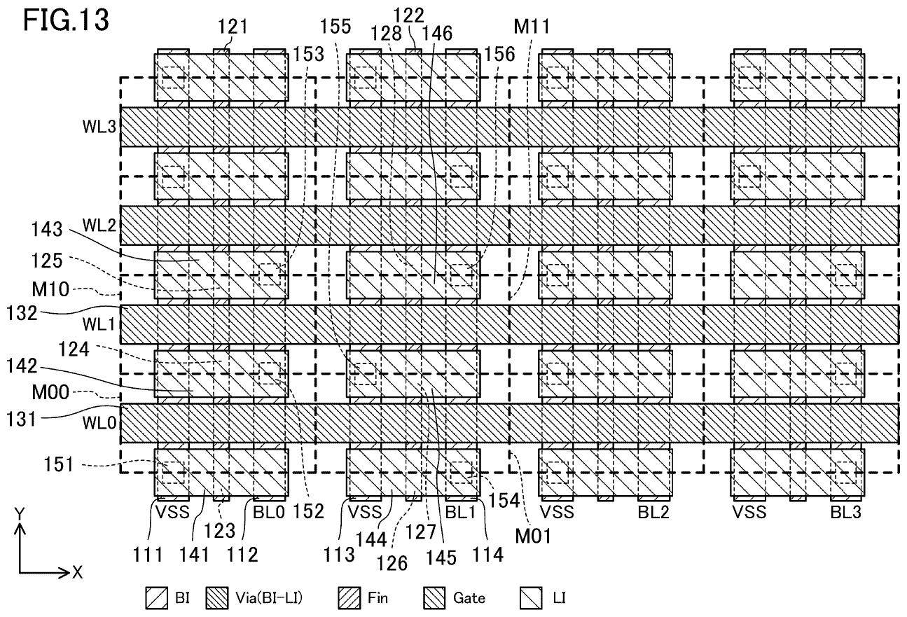

FIG. 13 is a view showing an example of the layout structure of a mask ROM of the second embodiment, and specifically a plan view of a memory cell array. FIG. 13 corresponds to the layout of (4×4) bits, and the broken lines define the bounds of the individual bits. That is, FIG. 13 shows a configuration of an array of memory cells, four arranged in the X direction and four in the Y direction. For example, two memory cells on the left in the lowermost row in the figure correspond to the memory cells M00 and M01 in the circuit diagram of FIG. 12, and two memory cells on the left in the second lowermost row in the figure correspond to the memory cells M10 and M11 in the circuit diagram of FIG. 12. Hereinafter, the structure related to the memory cells M00, M01, M10, and M11 will be mainly described.

The configuration of FIG. 13 is basically similar to the configuration of FIG. 2 shown in the first embodiment, except that each memory cell is constituted by one fin FET. Also, there are differences in the positions of contacts, etc. caused by the difference in the circuit structure of the mask ROM. Moreover, no dummy gate interconnect supplying VSS is provided. Note that description of configurations similar to those in the first embodiment is omitted here in some cases. Also, since the cross-sectional structure can be easily known by analogy from the cross-sectional views such as FIGS. 3A-3C, illustration of cross sections is omitted here.

As shown in FIG. 13, interconnects 111, 112, 113, and 114 extending in the Y direction are formed in the buried interconnect layer. The buried interconnects 111 and 113, which are interconnects supplying VSS, correspond to the ground power lines. The buried interconnects 112 and 114 respectively correspond to the bit lines BL0 and BL1.

Fin structures 121 and 122 extend in the Y direction. The memory cells M00 and M10 each have one fin FET formed of the fin structure 121, and the memory cells M01 and M11 each have one fin FET formed of the fin structure 122. Note that each memory cell may have two or more fin FETs.

Gate interconnects 131 and 132 extending in parallel in the X direction are formed. The gate interconnects 131 and 132 surround the peripheries of the fin structures 121 and 122 through gate insulating films (not shown). The gate interconnect 131 corresponds to the word line WL0 and is connected to the gates of the fin FETs of the memory cells M00 and M01. The gate interconnect 132 corresponds to the word line WL1 and is connected to the gates of the fin FETs of the memory cells M10 and M11.

Local interconnects 141, 142, 143, 144, 145, and 146 extending in the X direction are formed. Each of the local interconnects 141, 142, 143, 144, 145, and 146 is connected to a node (source or drain) of the fin FET of the corresponding memory cell. Specifically, the local interconnect 141 is connected to a portion 123 of the fin structure 121 that is to be a node of the fin FET of the memory cell M00. The local interconnect 142 is connected to a portion 124 of the fin structure 121 that is to be a common node of the fin FETs of the memory cells M00 and M10. The local interconnect 143 is connected to a portion 125 of the fin structure 121 that is to be a node of the fin FET of the memory cell M10. The local interconnect 144 is connected to a portion 126 of the fin structure 122 that is to be a node of the fin FET of the memory cell MOL. The local interconnect 145 is connected to a portion 127 of the fin structure 122 that is to be a common node of the fin FETs of the memory cells M01 and M11. The local interconnect 146 is connected to a portion 128 of the fin structure 122 that is to be a node of the fin FET of the memory cell M11.

Contacts 151, 152, 153, 154, 155, and 156 determine the memory values of the memory cells by their positions. That is, each of the memory cells M00, M01, M10, and M11 outputs memory data “1” when both nodes of the memory cell are connected to VSS through contacts or connected to the bit line BL through contacts. On the other hand, each of the memory cells M00, M01, M10, and M11 outputs memory data “0” when one of the nodes of the memory cell is connected to VSS through a contact and the other node is connected to the bit line BL through a contact.

In the configuration of FIG. 13, the memory cell M00 has memory data “0” since one node is connected to the buried interconnect 111 supplying VSS through the contact 151 and the other node is connected to the buried interconnect 112 corresponding to the bit line BL0 through the contact 152. The memory cell M10 has memory data “1” since both nodes are connected to the buried interconnect 112 corresponding to the bit line BL0 through the contacts 152 and 153. The memory cell M01 has memory data “0” since one node is connected to the buried interconnect 114 corresponding to the bit line BL1 through the contact 154 and the other node is connected to the buried interconnect 113 supplying VSS through the contact 155. The memory cell M11 has memory data “0” because one node is connected to the buried interconnect 113 supplying VSS through the contact 155 and the other node is connected to the buried interconnect 114 corresponding to the bit line BL1 through the contact 156.

The buried interconnect layer is formed to be buried in the substrate or a STI. For a buried interconnect, therefore, the resistance value can be reduced by increasing the length (thickness) of the buried interconnect in the depth direction. Thus, by forming the bit lines BL0 and BL1 as the buried interconnects 112 and 114, it is possible to curb decrease in the performance of the mask ROM without increasing the area.

Also, by forming the ground lines supplying VSS as the buried interconnects 111 and 113, in addition to the bit lines BL0 and BL1, the ground lines can be made to function as shield interconnects between the bit lines. It is therefore possible to prevent malfunctions, etc. caused by crosstalk noise.

As described above, according to this embodiment, the ROM cell M00, for example, is provided between the bit line 112 and the ground power line 111, and includes a fin FET connected to the word line 131 at its gate. The ROM cell M00 stores data depending on whether the source and drain of the transistor are connected to the same line or to different lines, out of the bit line 112 and the ground power line 111. Since the bit line 112 is formed in the buried interconnect layer, the resistance value of the bit line 112 can be reduced by increasing the thickness thereof in the depth direction. In this way, decrease in operating speed can be curbed without increase in area.

While the transistor included in the memory cell is a fin FET in the layout structure example described above, the transistor type is not limited to this, but may be a nanosheet FET, for example, as in the first embodiment.

### <Alteration 1>

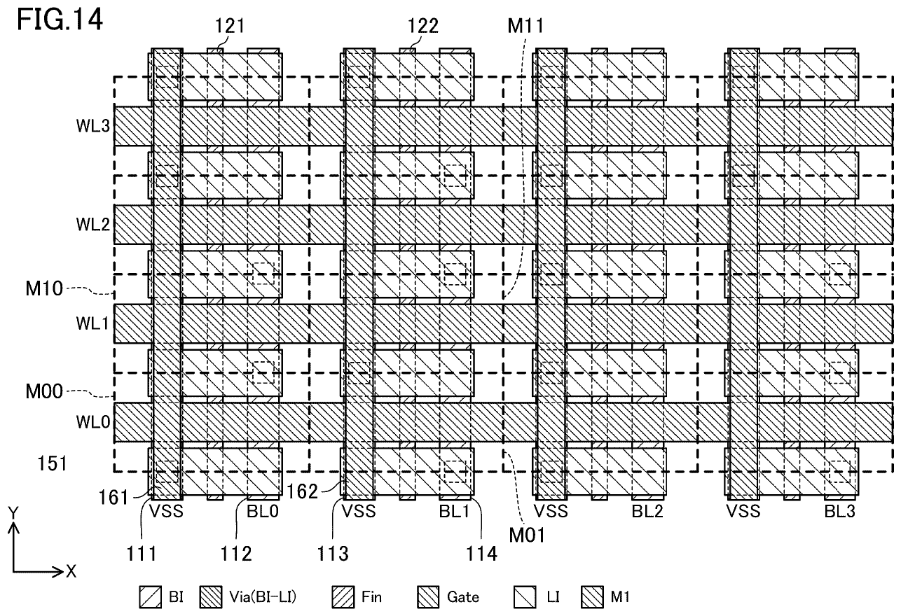

FIG. 14 is a plan view showing an example of the layout structure of a mask ROM of Alteration 1 of the second embodiment. In FIG. 14, interconnects 161 and 162 extending in the Y direction are provided in an M1 interconnect layer, in addition to the layout structure of FIG. 13. The M1 interconnects 161 and 162 correspond to the ground power lines supplying VSS. Although the M1 interconnects 161 and 162 are not connected to the memory cells, they are connected to the buried interconnects 111 and 113, respectively, outside the memory cell array.

According to this alteration, with the placement of the M1 interconnects 161 and 162 supplying VSS, power supply is strengthened and thus the stability of the operation of the memory cells improves.

### <Alteration 2>

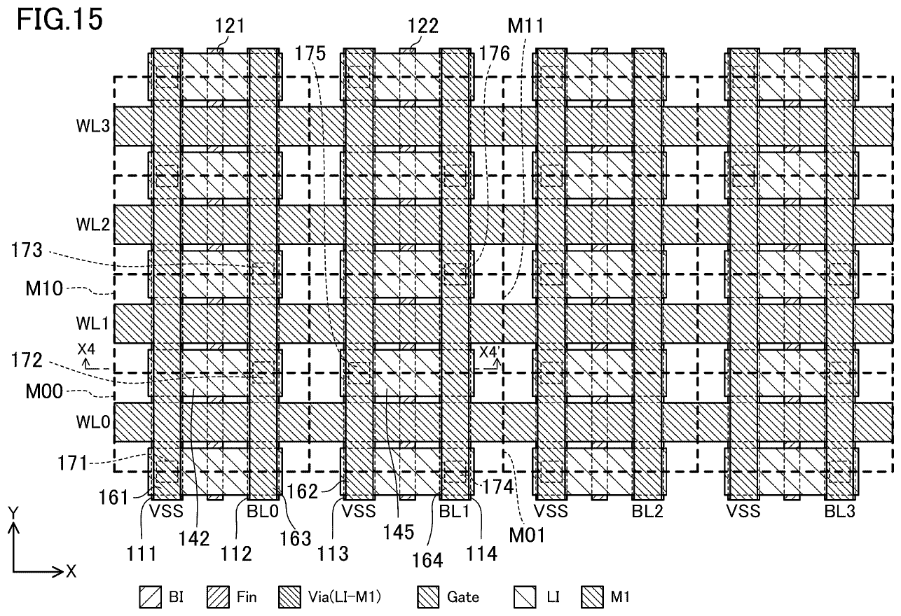

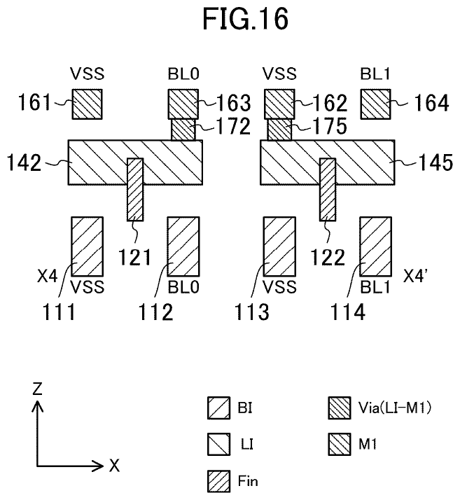

FIGS. 15 and 16 are views showing an example of the layout structure of a mask ROM of Alteration 2 of the second embodiment, where FIG. 15 is a plan view and FIG. 16 is a cross-sectional view taken along line X4-X4′ in FIG. 15.

In FIG. 15, interconnects 163 and 164 extending in the Y direction are provided in the M1 interconnect layer, in addition to the layout structure of FIG. 14. The M1 interconnects 163 and 164 correspond to the bit lines BL0 and BL1, respectively. No contacts are provided between the buried interconnects and the local interconnects, and contacts are provided between the M1 interconnects and the local interconnects. That is, in this alteration, contacts 171, 172, 173, 174, 175, and 176 determine the memory values of the memory cells by their positions.

Although the buried interconnects 112 and 114 corresponding to the bit lines are not connected to the memory cells, they are connected to the M1 interconnects 163 and 164, respectively, outside the memory cell array. That is, the buried interconnect 112 and the M1 interconnect 163 corresponding to the bit line BL0 are electrically connected to each other, and the buried interconnect 114 and the M1 interconnect 164 corresponding to the bit line BL1 are electrically connected to each other. Although the buried interconnects 111 and 113 corresponding to the ground power lines are not connected to the memory cells, they are electrically connected to the M1 interconnects 161 and 162, respectively, outside the memory cell array.

According to this alteration, the bit line BL0 is constituted by the buried interconnect 112 and the M1 interconnect 163, and the bit line BL1 is constituted by the buried interconnect 114 and the M1 interconnect 164. With this, the resistance values of the bit lines BL0 and BL1 can be further reduced. It is therefore possible to curb decrease in the operating speed of the mask ROM without increasing the area.

According to the present disclosure, decrease in the operating speed of the mask ROM can be curbed without increase in area. The present disclosure is therefore useful for downsizing, and improvement in the performance, of a semiconductor chip, for example.

1. A semiconductor memory device having a read only memory (ROM) cell, comprising:
a word line extending in a first direction;
a bit line extending in a second direction perpendicular to the first direction, formed in a buried interconnect layer; and
a ground power line extending in the second direction,
wherein
the ROM cell includes
a transistor provided between the bit line and the ground power line, connected to the word line at its gate and to the bit line at its drain, and
the ROM cell stores data depending on the presence or absence of connection between a source of the transistor and the ground power line.

2. The semiconductor memory device of claim 1, wherein
the ROM cell includes
a first local interconnect extending in the first direction, connected to the source of the transistor, and
a second local interconnect extending in the first direction, connected to the drain of the transistor,
the second local interconnect is connected to the bit line, and
data is stored depending on the presence or absence of connection between the first local interconnect and the ground power line.

3. The semiconductor memory device of claim 1, wherein
the ground power line is formed in the buried interconnect layer.

4. The semiconductor memory device of claim 1, wherein
the ground power line is formed in a first interconnect layer located above the buried interconnect layer.

5. The semiconductor memory device of claim 4, further comprising:
a second ground power line extending in the second direction, formed in the buried interconnect layer.

6. The semiconductor memory device of claim 4, further comprising:
a second bit line extending in the second direction, formed in the first interconnect layer,
wherein
the drain of the transistor of the ROM cell is connected to the bit line and the second bit line.

7. A semiconductor memory device having a read only memory (ROM) cell, comprising:
a word line extending in a first direction;
a bit line extending in a second direction perpendicular to the first direction, formed in a buried interconnect layer; and
a ground power line extending in the second direction,
wherein
the ROM cell includes
a transistor provided between the bit line and the ground power line, connected to the word line at its gate, and
the ROM cell stores data depending on whether a source and a drain of the transistor are connected to a same line, or different lines, out of the bit line and the ground power line.

8. The semiconductor memory device of claim 7, wherein
the ROM cell includes
a first local interconnect extending in the first direction, connected to the source of the transistor, and
a second local interconnect extending in the first direction, connected to the drain of the transistor, and
data is stored depending on whether the first and second local interconnects are connected to a same line, or different lines, out of the bit line and the ground power line.

9. The semiconductor memory device of claim 7, wherein
the ground power line is formed in the buried interconnect layer.

10. The semiconductor memory device of claim 9, further comprising:
a second ground power line extending in the second direction, formed in a first interconnect layer located above the buried interconnect layer.

11. A semiconductor memory device having a read only memory (ROM) cell, comprising:
a word line extending in a first direction;
a first bit line extending in a second direction perpendicular to the first direction, formed in a buried interconnect layer;
a second bit line extending in the second direction, formed in a first interconnect layer located above the buried interconnect layer and electrically connected to the first bit line; and
a ground power line extending in the second direction, formed in the first interconnect layer,
wherein
the ROM cell includes
a transistor provided between the second bit line and the ground power line, connected to the word line at its gate, and
the ROM cell stores data depending on whether a source and a drain of the transistor are connected to a same line, or different lines, out of the second bit line and the ground power line.

12. The semiconductor memory device of claim 11, wherein
the ROM cell includes
a first local interconnect extending in the first direction, connected to the source of the transistor, and
a second local interconnect extending in the first direction, connected to the drain of the transistor, and
data is stored depending on whether the first and second local interconnects are connected to a same line, or different lines, out of the second bit line and the ground power line.

13. The semiconductor memory device of claim 11, further comprising:
a second ground power line extending in the second direction, formed in the buried interconnect layer.
